(19) United States
(12) Patent Application Publication
(10) Pub. No.: US 2012/0313643 A1
(43) Pub. Date: Dec. 13, 2012

(54) MAGNETIC RESONANCE IMAGING (MRI) DEVICE NOISE DAMPENING SYSTEM

(76) Inventors: William A. Edelstein, Baltimore, MD (US); AbdEl-Monem El-Sharkawy, Baltimore, MD (US)

(21) Appl. No.: 13/495,265

(22) Filed: Jun. 13, 2012

Related U.S. Application Data
(60) Provisional application No. 61/496,408, filed on Jun. 13, 2011.
(60) Provisional application No. 61/567,310, filed on Dec. 6, 2011.
(60) Provisional application No. 61/594,690, filed on Feb. 3, 2012.

(51) Int. Cl. G01R 33/28

(52) U.S. Cl. 324/318

(57) ABSTRACT

Disclosed herein is a magnetic resonance imaging (MRI) device noise dampening system, including an adjustable vibration dampening suspension system arranged between a gradient winding assembly of the MRI device and a support structure supported by a primary magnet assembly of an MRI device, wherein the adjustable vibration dampening suspension system comprises: a plurality of separately inflatable support elements; a vibration reducing material coupled to at least one of a plurality of connecting elements associated with a gradient winding assembly of an MRI device; and/or an acoustic noise absorbing material at least partially filling a space containing a gradient winding assembly of an MRI device.

### CROSS REFERENCE TO RELATED APPLICATIONS

The present application claims the benefit of the following co-pending United States provisional applications; Application Ser. No. 61/496,408 filed 13 Jun. 2011, Application Ser. No. 61/567,310 filed 6 Dec. 2011, and Application Ser. No. 61/594,690 filed 3 Feb. 2012. The disclosures of the co-pending provisional applications are incorporated herein by reference in their entirety.

### FIELD OF THE INVENTION

The present invention relates generally to a magnetic resonance imaging (MRI) device, and more particularly to a noise dampening system for the MRI device.

### BACKGROUND OF THE INVENTION

MRI scanners are used in various fields, such as medical diagnostics. They typically create images based on the operation of a magnet, a gradient coil, or winding, assembly, and a radiofrequency coil(s). The magnet creates a uniform main magnetic field that makes unpaired nuclear spins, such as hydrogen atomic nuclei, responsive to radiofrequency excitation via the process of nuclear magnetic resonance (NMR). The gradient winding assembly imposes a series of pulsed, spatial-gradient magnetic fields upon the main magnetic field to give each point in the imaging volume a spatial identity corresponding to its unique set of magnetic fields during an imaging pulse sequence. The radiofrequency coil applies an excitation radiofrequency (rf) pulse that temporarily creates an oscillating transverse nuclear magnetization in the sample. This sample magnetization is then detected by the excitation rf coil or, in some cases, other rf coils. The resulting electrical signals are used by the computer to create magnetic resonance images. Typically, there is a radiofrequency coil and a gradient winding assembly within the magnet.

Magnets for MRI scanners can include superconductive-coil magnets, resistive-coil magnets, and permanent magnets. Known superconductive magnet designs include cylindrical magnets and open magnets. Cylindrical magnets typically have an axially-directed static magnetic field. In MRI systems based on cylindrical magnets, the radiofrequency coil, the gradient winding assembly, and the magnet are generally annularly-cylindrically shaped and are generally coaxially aligned, wherein the gradient winding assembly circumferentially surrounds the radiofrequency coil and wherein the magnet circumferentially surrounds the gradient winding assembly. Open magnets typically employ two spaced-apart magnetic assemblies (magnet poles) with the imaging subject inserted into the space between the assemblies. This scanner geometry allows access by medical personnel for surgery or other medical procedures during MRI imaging. The open space also helps the patient overcome feelings of claustrophobia that may be experienced in a traditional cylindrical magnet design.

A gradient winding assembly typically comprises a set of windings that produce the desired gradient fields. Such an assembly for a human-size whole-body MRI scanner typically weighs about 1000 kg. An assembly for small animal imaging (e.g., rabbits, dogs, monkeys, etc.) weighs about 100 kg. The windings consist of wires or conductors formed by cutting or etching sheets of conducting material (e.g., copper) to form current paths to generate desired field patterns. The wires or conducting coils or plates are themselves typically held in place by fiberglass overwindings plus an epoxy resin.

Generally, the various components of the MRI scanner represent sources and pathways of acoustic noise that can be objectionable or harmful to the human or animal subject being imaged and to the operator of the scanner. For example, the gradient winding assembly generates loud acoustic noises, which many medical patients find objectionable and which can damage hearing of humans or animals. The acoustic noises occur in the imaging region of the scanner as well as outside of the scanner. Known passive noise control techniques include locating the gradient winding assembly in a vacuum enclosure.

### SUMMARY OF THE INVENTION

A first aspect of the present invention provides a magnetic resonance imaging (MRI) device noise dampening system, comprising: an adjustable vibration dampening suspension system arranged between a gradient winding assembly of the MRI device and a support structure supported by a primary magnet assembly of an MRI device, wherein the adjustable vibration dampening suspension system comprises a plurality of separately inflatable support elements.

A second aspect of the present invention provides a magnetic resonance imaging (MRI) device noise dampening system, comprising: vibration reducing material coupled to at least one of a plurality of connecting elements associated with a gradient winding assembly of an MRI device.

A third aspect of the present invention provides a magnetic resonance imaging (MRI) device noise dampening system, comprising: an acoustic noise absorbing material at least partially filling a space containing a gradient winding assembly of an MRI device.

A fourth aspect of the present invention provides a magnetic resonance imaging (MRI) device noise dampening system, comprising: an adjustable vibration dampening suspension system arranged between a gradient winding assembly of the MRI device and a support structure supported by a primary magnet assembly of an MRI device, wherein the adjustable vibration dampening suspension system comprises a plurality of separately inflatable support elements; a vibration reducing material coupled to at least one of a plurality of connecting elements associated with the gradient winding assembly; and an acoustic noise absorbing material at least partially filling a space containing a gradient winding assembly of an MRI device.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 is a cross-sectional side view of an entire magnetic resonance imaging (MRI) device showing a whole-body cylindrical clinical MRI magnet, imaging volume and gradient winding assembly according to prior art embodiments.

FIG. 2 is a cross-sectional end view of one end of a prior art whole-body cylindrical clinical gradient winding assembly and support structure contained within the MRI device depicted in FIG. 1. It is to be understood that there is a similar support structure at the opposite end of the clinical gradient assembly.

FIG. 3 is a cross-sectional side view of a prior art self-contained, cylindrically symmetric insertable gradient assembly containing a gradient winding assembly that can be inserted into an MRI magnet and used to image animals or parts of human subjects such as the head or limbs.

FIG. 4 is a schematic cross-sectional end view of the gradient support structure at one end of the insertable MRI gradient assembly shown in FIG. 3 that is held in place inside a containing cylinder by an O-ring. It is to be understood that there is a similar gradient support structure at the opposite end of the insertable MRI gradient assembly.

FIG. 5 is a schematic cross-sectional view of one end of a cylindrical clinical gradient winding assembly held in place using a system of two pairs of inflatable supports according to an embodiment of the current invention, one pair adjusting the vertical position, restoring constants and damping and a second, lateral pair adjusting the horizontal position, restoring constants and damping. It is to be understood that there is a similar system of two pairs of inflatable supports at the opposite end of the clinical gradient winding assembly.

FIG. 6 is a schematic cross-sectional view of one end of a cylindrical clinical gradient winding assembly held in place using a system of three inflatable supports, according to an embodiment of the current invention, adjusting vertical and horizontal positions, vertical and horizontal restoring constants. It is to be understood that there is a similar system of three inflatable supports at the opposite end of the clinical gradient winding assembly.

FIG. 7 is a schematic cross-sectional view of one end of a cylindrical clinical gradient winding assembly held in place using a system of two inflatable supports, according to an embodiment of the current invention, adjusting vertical position and maintaining horizontal position by virtue of the angular extent of the inflatable supports and establishing restoring constants. It is to be understood that there is a similar system of two inflatable supports at the opposite end of the clinical gradient winding assembly.

FIG. 8 is a schematic cross-sectional view of one end of a cylindrical insertable gradient assembly containing a gradient winding assembly held in place using a system of four inflatable supports, according to an embodiment of the current invention, adjusting vertical and horizontal positions, vertical and horizontal restoring constants. It is to be understood that there is a similar system of four inflatable supports at the opposite end of the insertable gradient assembly.

FIG. 9 is a schematic cross-sectional view of one end of a cylindrical insertable gradient assembly containing a gradient winding assembly held in place using a system of three inflatable supports, according to an embodiment of the current invention, adjusting vertical and horizontal positions, vertical and horizontal restoring constants. It is to be understood that there is a similar system of three inflatable supports at the opposite end of the insertable gradient assembly.

FIG. 10 is a schematic cross-sectional view of one end of a cylindrical insertable gradient assembly containing a gradient winding assembly held in place using a system of two inflatable supports, according to an embodiment of the current invention, adjusting vertical position and maintaining horizontal position by virtue of the angular extent of the inflatable supports and establishing restoring constants. It is to be understood that there is a similar system of two inflatable supports at the opposite end of the insertable gradient assembly.

FIG. 11 is a schematic cross-sectional view of one end of a cylindrical insertable gradient assembly containing a gradient winding assembly held in place using a system of three inflatable supports along with a control system that monitors the gradient winding assembly position and inflated support pressure and adjusts the inflated support pressure to maintain the position of the gradient winding assembly.

FIG. 12 is a cross-sectional side view of a cylindrical gradient winding assembly contained in an enclosure with wires or other connections to the gradient penetrating through the enclosing structure according to prior art.

FIG. 13 is a cross-sectional side view of a cylindrical gradient winding assembly contained in an enclosure with wires or other connections to the gradient having damping/elastic materials tightly attached to the connections both inside and outside the enclosure, with the connections penetrating through the enclosing structure attached and sealed to the enclosing structure by vibration isolating damping/elastic materials, and strain relief loops, according to an embodiment of the invention.

FIG. 14 is a cross-sectional side view of an entire magnetic resonance imaging (MRI) device showing a whole-body cylindrical clinical MRI magnet, imaging volume, and gradient winding assembly inside a sealed enclosure, which sealed enclosure can be evacuated in order to prevent sound transmission, according to prior art.

FIG. 15 is a cross-sectional side view of an entire magnetic resonance imaging (MRI) device showing a whole-body cylindrical clinical MRI magnet, imaging volume, and gradient winding assembly inside a sealed enclosure, which sealed enclosure contains sound absorbing and sound blocking material in order to prevent sound transmission, according to an embodiment of the present invention.

FIG. 16 is cross-sectional side view of a self-contained, cylindrically symmetric gradient assembly, including a gradient winding assembly within a sealed enclosure, that can be inserted into an MRI magnet and used to image animals or parts of human subjects such as the head or limbs, which sealed enclosure can be evacuated in order to prevent sound transmission, according to prior art.

FIG. 17 is a cross-sectional side view of a self-contained, cylindrically symmetric gradient assembly, including a gradient winding assembly within a sealed enclosure, that can be inserted into an MRI magnet and used to image animals or parts of human subjects such as the head or limbs, which sealed enclosure can be filled with sound absorbing and sound blocking material to prevent sound transmission according to an embodiment of the present invention.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION OF THE INVENTION

Generally, embodiments of the present invention include dampening the acoustic noise generated by the various components of the MRI device. For instance, the gradient winding assembly generates a large portion of the acoustic noises, which may occur in the imaging region of the scanner as well as outside of the scanner.

In some cases, large pulsed electrical currents, typically 200 amperes (A) or more, with risetimes and durations typically in the submillisecond to millisecond range, are applied to the windings of the gradient winding assembly. Because these windings are located in strong static magnetic fields (e.g., 1.5 tesla (T) to 3 T for a typical human clinical imager to much higher values for research systems and animal MRI systems), the currents interact with the static field and strong Lorentz forces are exerted on different parts of the gradient winding assembly. These forces in turn move, compress, expand, bend or otherwise distort the gradient winding assembly. It will be readily understood by those skilled in the art that the frequencies of the acoustic noise so generated may be in the audio frequency range. There may be strong components of noise from 50 hertz (Hz) and below to several kHz at the upper end of the frequency range.

In order to decrease the level of acoustic noise reaching a certain target location, e.g., the imaging volume or observer positions, it is necessary to either lessen the noise produced at the source or to cut off or decrease the efficacy of the pathway along which vibrations or acoustic noise can be conveyed to the imaging volume, the cryostat, or to other external parts of the MRI device and ultimately create acoustic noise that can be heard by the imaging subject, scanner operator, attending physicians, or other scanner staff in the vicinity of the scanner. In short, this can be referred to as the source pathways of noise production-transmission.

There are several possible pathways of noise transmission in an MRI device. For instance, some vibrations may be conveyed mechanically from the gradient winding assembly to the imaging volume, the cryostat, or to other external parts of the MRI scanner via the gradient winding assembly suspension system. As another example, vibrations may be conveyed mechanically from the gradient winding assembly via the wires, hoses, video inspection fiber optic cables, or any connections that must penetrate through any enclosure containing the gradient winding assembly and cause vibrations in the gradient winding enclosure, the cryostat, or other external parts of the MRI scanner. In still further embodiments, sound originating at the gradient winding assembly may be transmitted via air and vibrations to the imaging volume.

In the case of vibrations that can be conveyed mechanically from the gradient winding assembly to the imaging volume, the cryostat, or other external parts of the MRI scanner via the gradient coil assembly support, one way to decrease the transmitted vibrations is to use passive vibration isolation mounts for the gradient coil assembly. Previous attempts, according to the prior art, have included the use of isolation mounts for machinery so that vibrations from machinery supported by the isolation mounts are not transmitted to surrounding structure that supports the isolation mounts. Conventional isolation mounts include those of the elastomeric type, and those of the spring type. These types of isolation mounts can be designed such that the natural frequency of vibration of the mounts and the machinery is less than the important vibration frequencies of the machinery in order to provide vibration isolation.

In one previous approach to providing a vibration isolation mount for a gradient winding assembly in an MRI system, solid metal brackets are mounted on the gradient winding assembly and corresponding solid metal brackets attached to the cryostat. The gradient winding assembly is positioned so that the brackets are aligned and elastomeric pads (for example, rubber) are positioned between each cryostat bracket and the corresponding gradient winding assembly bracket. With this configuration, the transmission of vibrations from the gradient coil assembly to the cryostat is attenuated by the elastomeric pads.

Unfortunately, there is a limit to the degree of passive attenuation achievable by use of elastomeric pads or spring isolation mounts in an MRI system, which work similarly, as described. This is partly because there is little free space between the gradient winding assembly and the cryostat bore, so it is difficult to place elastomeric pads or springs with a low spring constant that, with the gradient winding assembly, would have a low resonant mechanical frequency. Such low spring constant elastomeric pads or springs would require significant compression in order to fit in the available space and have the requisite force to support the gradient winding assembly.

One approach consistent with the present invention is to position an inflatable support, which may be in the form of a sealed rubber tube, between the object lifted (in this case the gradient winding assembly) and the support structure used. The sealed rubber tube can start flattened and therefore take up very little vertical space. It can then be inflated to lift the supported object a short distance. Thus little clearance is required between the gradient winding assembly and the surrounding magnet cryostat inner bore.

For the inflatable support, however, the lateral elastic properties of the sealed rubber tube material must be such that the pressure needed to lift the gradient coil assembly is contained in the lateral expansion of the surrounding sealed rubber tube, as is the case for a tubeless tire. Alternatively, the sealed rubber tube can be contained in a constrained manner, such as, for instance, an inner tube within a surrounding tire, which prevents excessive lateral expansion of the sealed rubber tube.

In such an inner tube format, an inflatable support in the form of a sealed rubber tube within a tire like structure, similar to a typical tire inner tube, which is positioned between the gradient winding assembly and the support, the sealed rubber tube and containing tire-like structures can also start flattened and therefore take up very little vertical space. It can also then be inflated to lift the supported object a short distance. Thus little clearance is required between the gradient winding assembly and the surrounding magnet cryostat inner bore.

Generally speaking, softer pads or springs produce greater attenuation than harder pads or stiffer springs. However, the pads or springs underneath the gradient winding assembly must be able to support the gradient winding assembly weight. Also, pads or springs that are too soft might permit excessive motion of the gradient coil assembly in response to Lorentz forces, in which case image quality could be adversely affected. Pad or spring stiffness is thus a tradeoff between keeping the gradient winding assembly precisely positioned, on the one hand, and attenuating vibration transmission on the other.

For a support which is only below the gradient winding assembly, the height of the gradient winding assembly above its support and the inflatable support spring constant are interdependent. Generally speaking, increasing the gradient winding assembly height increases the spring constant and lowering the gradient winding assembly height decreases the spring constant. However, it would be desirable to have independent control of position and spring constant in order to both precisely position the gradient winding assembly and control the vibration transmission and Lorentz-force induced motion.

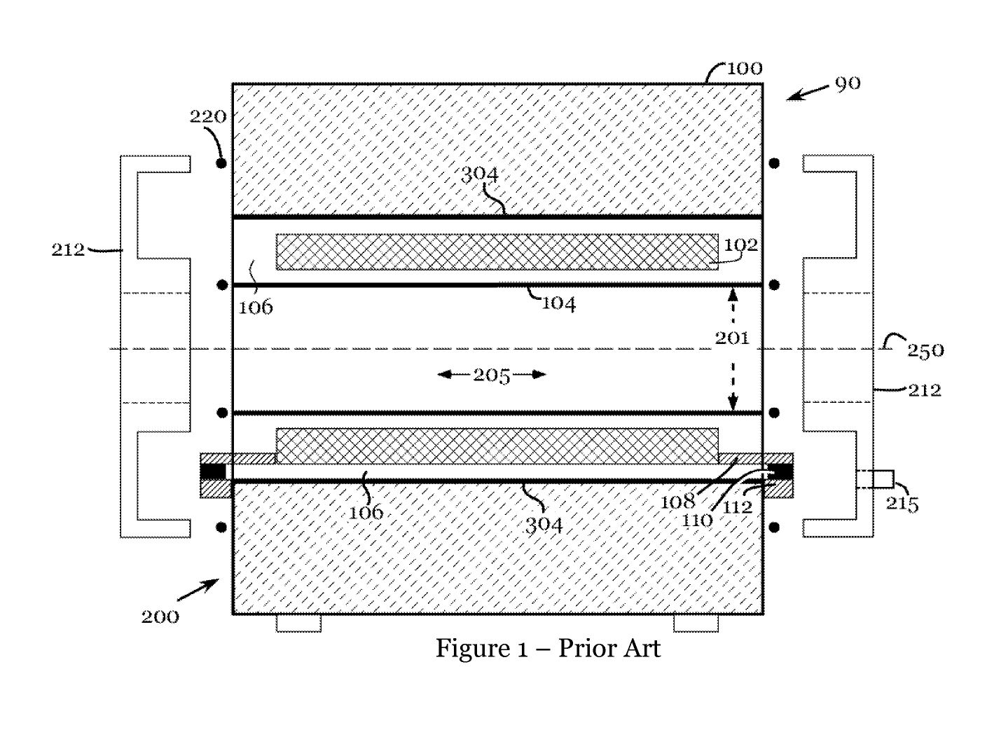

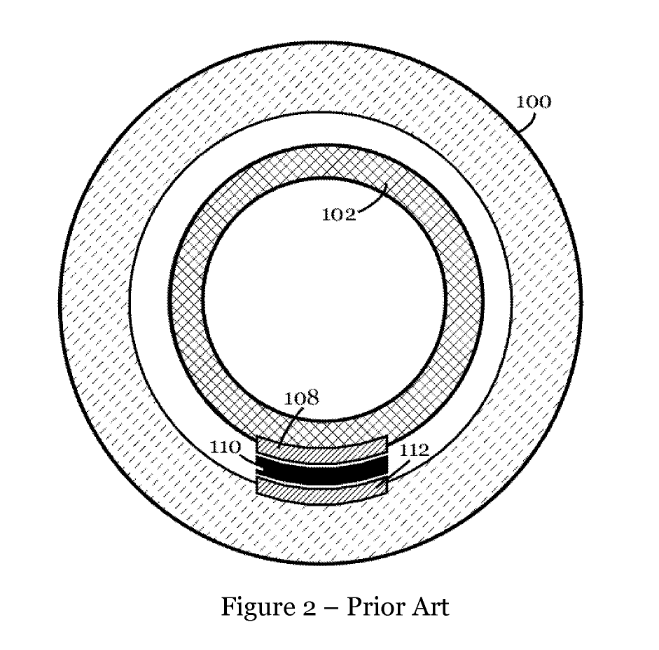

FIG. 1 is a schematic illustration of a magnetic resonance imaging (MRI) device 90 to which embodiments of the present invention are applicable. Throughout the figures, like numerals represent like elements. FIGS. 2-13 show gradient winding assemblies that would be used in closed, cylindrical magnet assemblies such as magnet 200. As illustrated, MRI device 90 is based on a closed, cylindrical superconducting magnet assembly 200. It is to be appreciated by one skilled in the art that the functions and descriptions of the present invention are equally applicable to an open magnet configuration in which the imaging subject is inserted perpendicular to the static magnetic field.

Referring to FIG. 1, this type of magnet assembly comprises an inner surface referred to as a magnet warm bore 304 and a cryostat shell 100 disposed radially around the outer surface. The magnet assembly further comprises end cap seals 212. When end cap seals 212 are secured against rubber gaskets 220 positioned between end cap seals 212 and cryostat shell 100, and secured against other rubber gaskets 220 positioned between end cap seals 212 and patient tube 104, an airtight space containing the gradient winding assembly 102 is created.

Typically, cryostat shell 100 encloses a superconductive magnet (not shown) that, as is well-known, includes several radially-aligned and longitudinally spaced-apart superconductive coils, each capable of carrying a large electric current. The superconductive coils produce a homogeneous, main static magnetic field, known as B₀, typically in the range from 0.5 T to 8 T, aligned along the center axis 250. Cryostat shell 100 is generally metallic, typically steel or stainless steel.

A patient or imaging subject (not shown) is positioned within a cylindrical imaging volume 205 surrounded by patient bore tube 104. Bore tube 104 is typically made of electrically non-conducting material such as fiberglass. Gradient winding assembly 102 is disposed around in a spaced apart coaxial relationship therewith and generates time-dependent gradient magnetic field pulses in a known manner. Radially disposed around gradient winding assembly 102 is cryostat shell 100 also including warm bore 304. Cryostat shell 100 contains the magnet that produces the static magnetic field necessary for producing MRI images, as described above.

Also shown in FIG. 1 is a schematic view of vibration dampening suspension system between gradient winding assembly 102 and cryostat 100. In this configuration, gradient winding assembly 102 is connected to brackets 108. Cryostat 100 is connected to brackets 112, and vibration dampening suspension system 110, typically rubber, is inserted between brackets 108 and 112, supports the gradient winding assembly 102, and reduces transmission of vibrations the gradient winding assembly 102 to the cryostat 100.

FIG. 2 shows an end view of a prior art embodiment of passive vibration isolation.

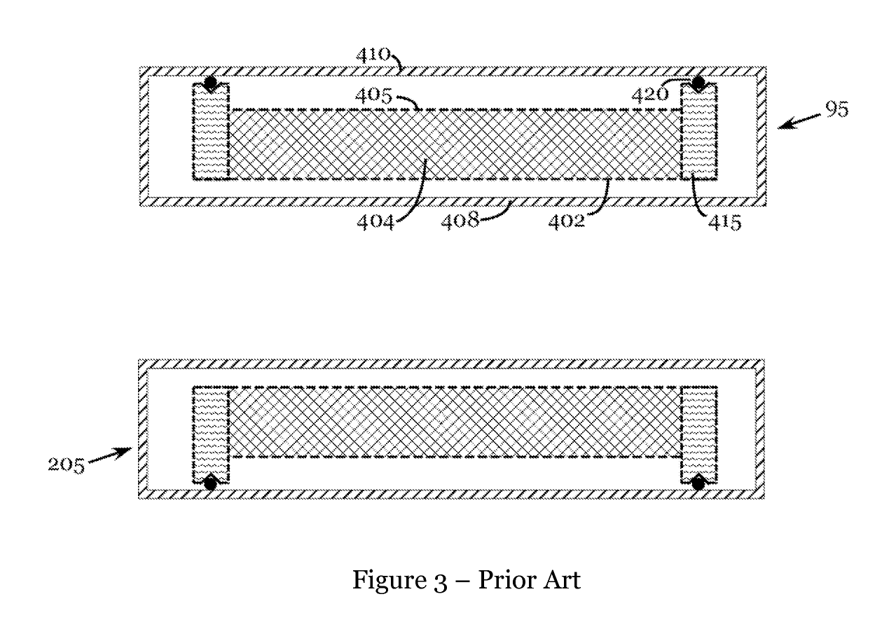

FIG. 3 illustrates an insertable gradient fixture 95 according to prior art embodiments, typically for use with small animal imaging systems. Gradient winding assembly 404 is enclosed in an annular container 205. Gradient winding assembly 404 is attached at its ends to annular flanges 415 which are secured by O-rings 420 to the inside of an outer wall 410 of annular container 205. It is also possible to directly secure gradient winding assembly 404 to outer wall 410 by using O-rings or other means.

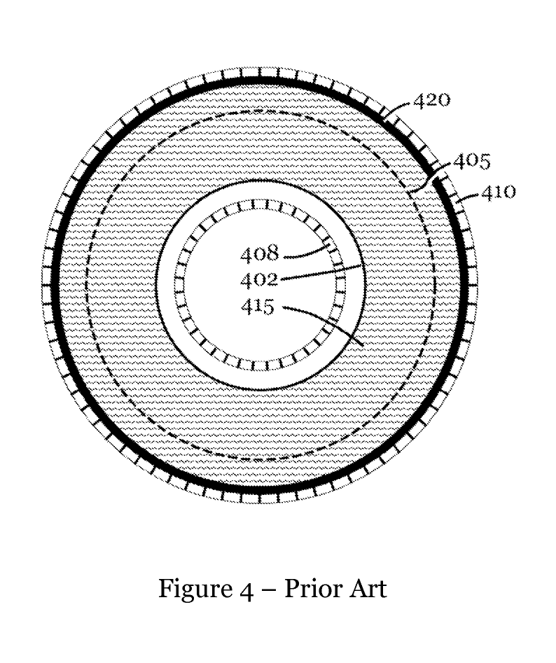

FIG. 4 shows an end view of one end of the prior art insertable gradient fixture 95.

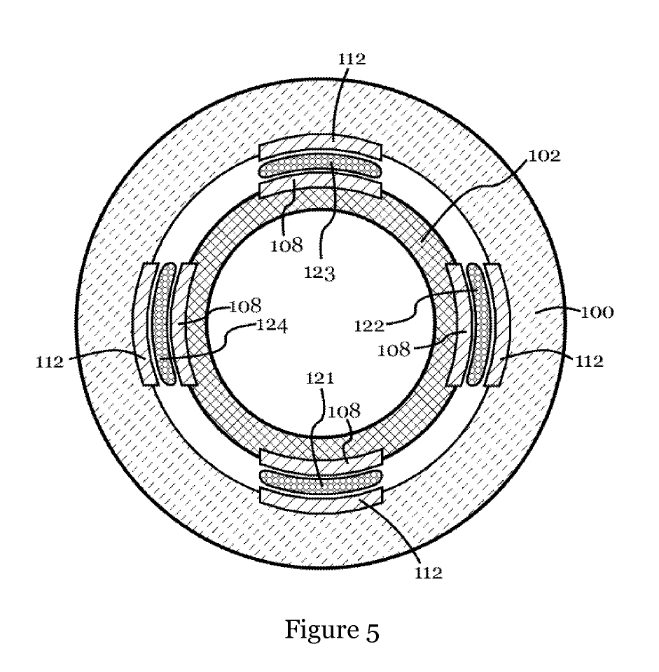

FIG. 5 shows an end view of one end of a clinical gradient winding assembly according to one embodiment of the present invention. Illustrated is an adjustable vibration dampening system comprising inflatable support elements 121, 122, 123 and 124 that position gradient winding assembly 102 concentrically relative to a primary magnet assembly, the magnet cryostat 100 in this illustrative embodiment. In this embodiment, inflatable support elements 121-124 are contained between brackets 112 that are attached to magnet cryostat 100 and brackets 108 that are attached to gradient winding assembly 102. It is to be understood that there is a similar support structure at the opposite end of the clinical gradient winding assembly.

It will be readily understood by those skilled in the art that the inflatable support elements 121-124 can be placed to support gradient winding assembly 102 with other arrangements. For example, inflatable support elements 121-124 can be placed directly between the inner bore of magnet cryostat 100 and the outer surface of gradient winding assembly 102.

As described herein, inflatable support elements 121, 122, 123 and 124 may also set spring constants for movement of gradient winding assembly 102 relative to magnet cryostat 100. As also described herein inflatable support elements 121, 122, 123 and 124 may also set coefficients of attenuation of vibration between gradient winding assembly 102 and magnet cryostat 100.

As also described herein, inflatable support elements 121 and 123 can control the vertical position of gradient winding assembly 102 relative to magnet cryostat 100. Inflatable support element 121 will typically be inflated to a pressure at least adequate to support half the weight of gradient winding assembly 102. An equivalent inflatable support element 121 at the opposite end of the system also would typically support the remaining half of the weight of gradient winding assembly 102. Inflatable support element 123 may also be utilized to help determine the vertical position of gradient winding assembly 102.

According to embodiments of the present invention, it is possible to set the spring constants k1 and k3 of inflatable support elements 121 and 123 respectively in FIG. 5. This may allow for the gradient winding assembly 102 to be located in a vertically central position relative to magnet cryostat 100. In one embodiment, setting the spring constants is achieved by setting the pressure of inflatable support elements 121 and 123 by any now known or later developed method. Further, each inflatable support element in each embodiment may be separately inflatable, allowing for each inflatable support element to have its own relative pressure set in order to individually control the pressure, spring constant, and coefficient of vibration attenuation.

In some embodiments, it is possible to set the spring constants k1 and k3 to a stiffness that prevents excessive motion of the gradient 102 relative to magnet cryostat 100. Such motion could cause blurring or other artifacts in MRI images made with the gradient winding assembly 102 suspended at inadequate spring constants.

The net spring constant k13 of gradient winding assembly 102 for vertical deflection relative to the center of magnet cryostat 100 is approximately given by k13==k1+k3.

Vibrations of the gradient winding assembly 102 can be transmitted via inflatable support elements 121 and 123 to the magnet cryostat to produce audible noise, defining the coefficients of attenuation of vibration. Accordingly, the spring constants k1 and k3 may be set so that the resonant frequency fᵥ of the mass of gradient winding assembly 102 oscillating relative to magnet cryostat 100 is as low as possible, since the power of the transmitted vibrations at frequency f higher than fᵥ falls off according to the equation power∝(fᵥ/f)². Typically, fᵥ will be set to a few Hz. The stiffness k13 and consequent resonant frequency fᵥ should, however, be high enough to prevent excessive motion of the gradient winding assembly 102 that might cause artifacts in the resulting MRI image.

Also illustrated in FIG. 5, inflatable support elements 122 and 124 may be able to adjust the horizontal position of gradient winding assembly 102 relative to magnet cryostat 100. As discussed above, the pressure in inflatable support elements 122 and 124 may be adjusted first to center gradient winding assembly 102 horizontally relative to cryostat 100. Second, the pressure in inflatable support elements 122 and 124 may be adjusted so that the spring constants k2 and k4 yield a net spring constant (k24=k2+k4) stiff enough to prevent excessive motion but soft enough so that vibrations transmitted by the spring action of the inflatable support elements 122 and 124 from gradient winding assembly 102 to magnet cryostat 100 are substantially attenuated.

As can be seen in FIG. 5, the inflatable support elements 121-124 may transmit vibrations via surface vibrations of the material comprising the inflatable support elements 121-124. Accordingly, inflatable support elements 121-124 may be comprised of a material that has good vibration damping properties, regardless of the inflation. For instance, plastics and elastomers may be utilized. This may include, but is not limited to, natural and synthetic rubber.

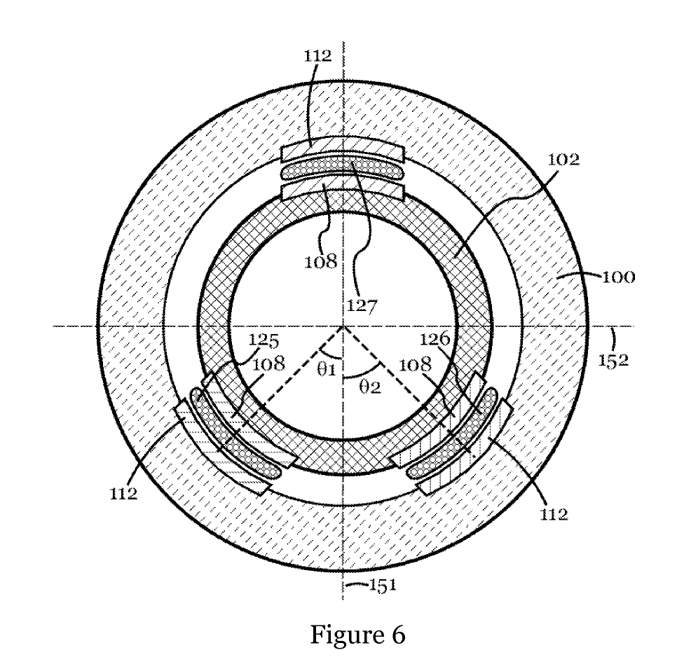

FIG. 6 illustrates an end view of one end of a clinical gradient winding assembly using inflatable support elements 125, 126 and 127 that position gradient winding assembly 102 concentrically relative to magnet cryostat 100. Inflatable support elements 125, 126 and 127 can also set spring constants for movement of gradient winding assembly 102 relative to magnet cryostat 100. Inflatable support elements 125, 126 and 127 may also set coefficients of attenuation of vibration between gradient winding assembly 102 and magnet cryostat 100. The attenuation of vibration is somewhat dependent upon the spring constant of inflatable support elements 125, 126 and 127, as set by the pressure, and the damping properties as determined by the chosen material of inflatable support elements 125, 126 and 127. It is to be understood that there is a similar support structure at the opposite end of the clinical gradient winding assembly.

As shown In FIG. 6, inflatable support element 127 may apply a vertical force to gradient winding assembly 102, while inflatable support elements 125 and 126 can each apply both vertical and horizontal forces to gradient winding assembly 102. As described above, pressures in inflatable support elements 125-127 can be set to adjust the position of gradient winding assembly 102 and to adjust the horizontal and vertical spring constants of the motion of gradient winding assembly 102 relative to magnet cryostat 100.

In FIG. 6, the angular placements of θ1 and θ2 of inflatable support elements 125 and 126 relative to the vertical center line 151 can be varied to change the relative horizontal and vertical forces applied by inflatable support elements 125 and 126. In some embodiments θ1 may be approximately the same as θ2. However, in other embodiments, θ1 and θ2 may be completely different angles. As illustrated, inflatable support elements 125-127 are in a substantially triangular set up. It should be understood that they may be arranged approximately 120 degrees apart from one another, in some embodiments.

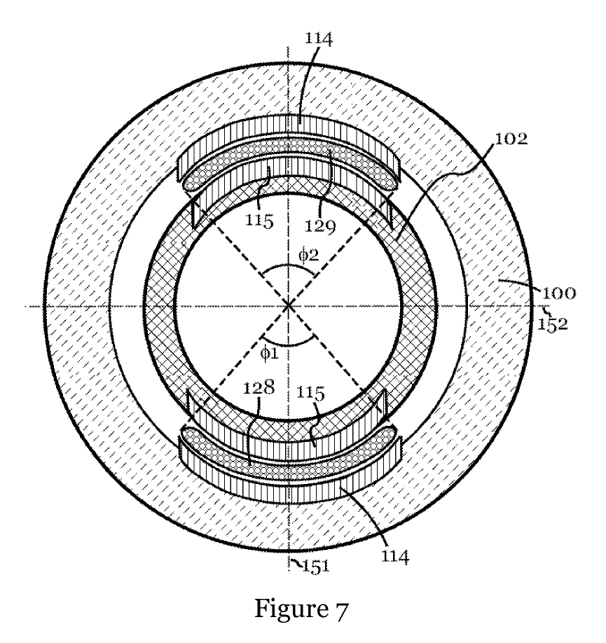

In FIG. 7, one end of the clinical gradient winding assembly 102 is held in place by inflatable support elements 128 and 129. Inflatable support elements 128 and 129 may supply both vertical and horizontal forces and vertical and horizontal spring constants.

As illustrated, the angular sizes Φ1 and Φ2 of inflatable support elements 128 and 129 can be varied to change the relative horizontal and vertical forces applied by inflatable support elements 128 and 129. In some embodiments Φ1 may be approximately the same as Φ2. However, in other embodiments, Φ1 and Φ2 may be completely different angles. In some embodiments, inflatable support elements 128 and 129 may be substantially centered vertically at the top and bottom of vertically upward and vertically downward radial axes. However, in other embodiments, inflatable support elements 128 and 129 may be centered on horizontal radial axes, or even on entirely different axes which are neither horizontal nor vertical. It is to be understood that there is a similar support structure at the opposite end of the clinical gradient winding assembly.

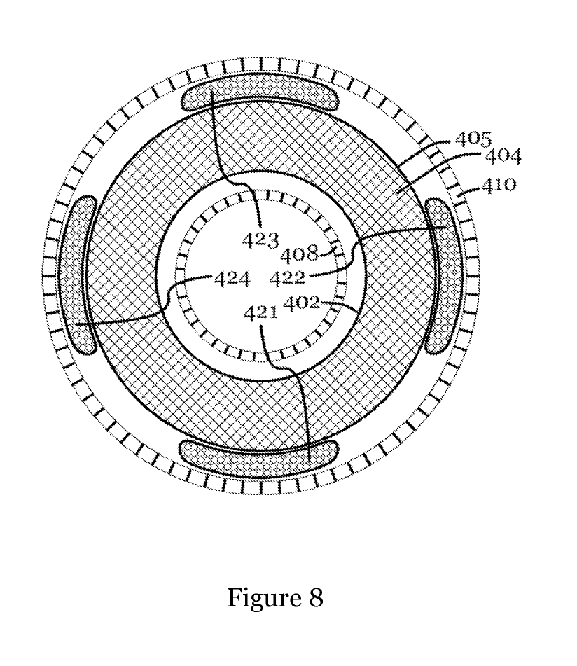

FIG. 8 shows an end view of one end of an insertable gradient winding assembly 404 using inflatable support elements 421, 422, 423 and 424 to position one end of gradient winding assembly 404 concentrically relative to outer structural cylinder 410 and inner structural cylinder 408. In this embodiment, inflatable support elements 421-424 are positioned between gradient winding assembly 404 and outer containment cylinder 410. It is to be understood that there is a similar support structure at the opposite end of the insertable gradient winding assembly 404.

It will be readily understood by those skilled in the art that the inflatable support elements 421-424 in FIG. 8 can be placed to support gradient winding assembly 404 with other arrangements. For example, inflatable support elements 421-424 can be placed between gradient winding assembly 404 and inner containment cylinder 408. Further, inflatable support elements 421-424 can be placed between brackets attached to gradient winding assembly 404 and brackets attached to outer containment cylinder 410.

In FIG. 8, the functions of inflatable support elements 421-424 are analogous to the functions of inflatable support elements 121-124 in FIG. 5. That is, inflatable support elements 421 and 423 may determine the vertical position of one end of gradient winding assembly 404 and the vertical spring constant for vertical vibrations of gradient winding assembly 404 relative to outer cylinder container 410 and inner cylinder container 408. Inflatable support elements 422 and 424 may determine the horizontal position of one end of gradient winding assembly 404 and the horizontal spring constant for horizontal vibrations of gradient winding assembly 404 relative to outer cylinder container 410 and inner cylinder container 408.

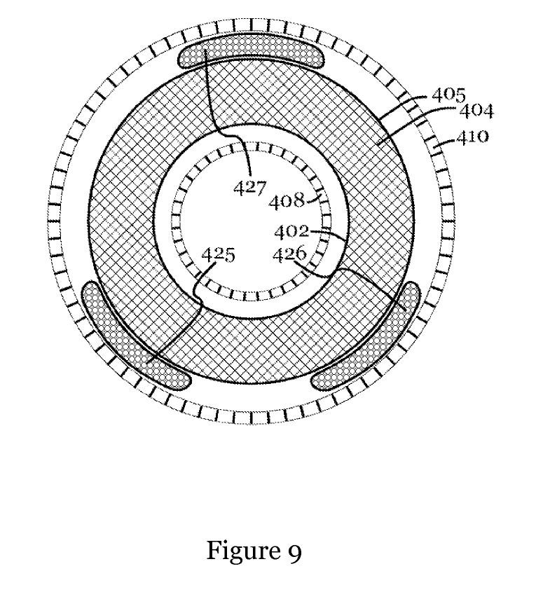

FIG. 9 shows an end view of one end of an insertable gradient assembly 404 using inflatable support elements 425, 426, and 427 to position one end of gradient winding assembly 404 concentrically relative to outer structural cylinder 410 and inner structural cylinder 408. In this embodiment, inflatable support elements 425-427 are positioned between gradient winding assembly 404 and outer containment cylinder 410. It is to be understood that there is a similar support structure at the opposite end of the clinical gradient winding assembly 404.

In FIG. 9, the functions of inflatable support elements 425-427 are analogous to the functions of inflatable support elements 125-127 in FIG. 6.

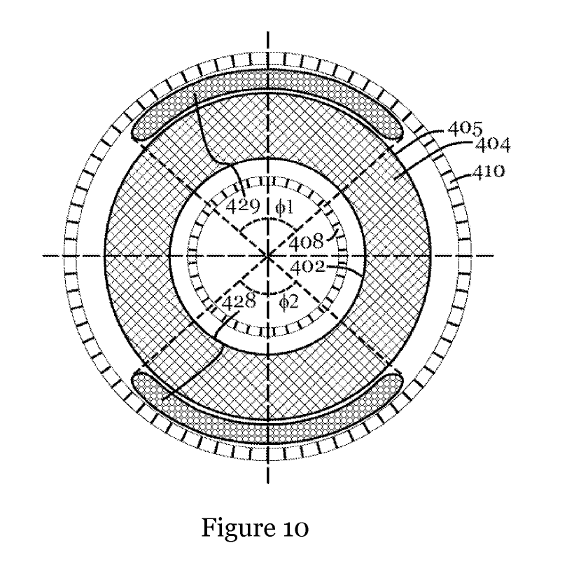

FIG. 10 shows an end view of one end of an insertable gradient winding assembly where inflatable support elements 428 and 429 supply both vertical and horizontal forces and vertical and horizontal spring constants.

In FIG. 10, the functions of inflatable support elements 428-429 are analogous to the functions of inflatable support elements 128-129 in FIG. 7.

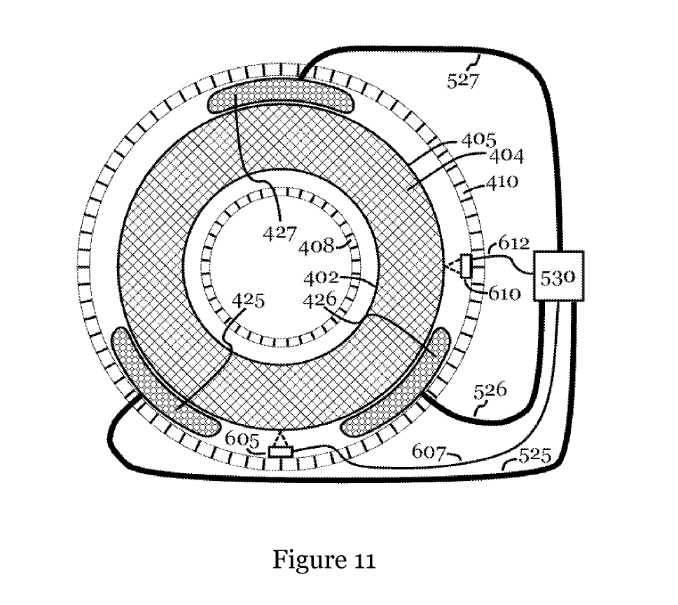

FIG. 11 illustrates one end of an insertable gradient winding assembly 404 supported by three inflatable support elements 425, 426 and 427 as described above along with an automated control system to sense and control the parameters that determine the position of one end of gradient winding assembly 404 relative to outer containment cylinder 410.

FIG. 11 shows position sensing elements 605 and 610 sensing, respectively, the vertical and horizontal position of one end of gradient winding assembly 404 relative to outer containment cylinder 410. In some embodiments, sensing elements 605 and 610 may be laser sensing elements; however any now known or later developed sensing elements may be utilized. Elements 605 and 610 are illustrated as having respective electrical outputs 607 and 612 connected to a control device 530. FIG. 11 also illustrates air lines 525, 526 and 527 attached respectively to inflatable support elements 425, 526 and 427. The other ends of the air lines 525-527 are attached to control device 530. Any deviation of the one end of gradient winding assembly 404 from the desired position, as may be detected by laser sensing elements 605 and 610, can be used by control device 530 to change the relative pressures in inflatable support elements 425-427 in order to alter the position of the one end of gradient winding assembly 404 relative to outer containment structure 410. As previously discussed, it should be clear that control device 530 may be used to adjust each inflatable support element separately, allowing for each inflatable support element to have its own relative pressure set in order to individually control the pressure, spring constant, and coefficient of vibration attenuation.

In another mode of operation, the pressure in inflatable support elements 425-427 can be sensed by control device 530 which can then alter the pressures in inflatable support elements 425-427, separately, via air lines 525-527 to a set of predetermined values, thereby restoring the forces on and the positions of gradient winding assembly 404 relative to outer containment cylinder according to the predetermined values. In this mode of operation, the laser position sensors may not be necessary.

In any of the above-described embodiments, inflatable support elements can be used between the ends of the gradient winding assembly and the inside ends of the containing structure in order to control longitudinal motion of the gradient winding assembly. The pressure can also be altered in order to control the stiffness of the inflatable support elements in order to control the amount of vibration that travels through the containing structure outside of the MRI device.

In any of the above-described embodiments, more, or fewer, inflatable support elements can be used between the gradient winding assembly and surrounding support structures and varying amounts of pressure can be used to control the position of the gradient winding assembly and the spring constants of the gradient winding assembly relative to surrounding support structures.

In any of the above-described-embodiments, there may be position-sensing elements that measure the position of the gradient winding assembly relative to the magnet cryostat or gradient assembly container and, using manual or automatic electronics, adjust the pressures in the inflatable support elements, thereby maintaining, altering, or restoring the position of the gradient winding assembly to a desired position.

In any of the above-described embodiments, the two opposite ends of the gradient winding assembly may have the same or different numbers and arrangements of inflatable support elements.

In any of the above-described embodiments, there may be more than two sets of inflatable support elements at the two ends of the gradient winding assembly. For example, there might be another set of inflatable support elements approximately in the middle of the gradient winding assembly, or interspersed throughout the gradient winding assembly.

In summary, some embodiments of the current invention can include an apparatus for reducing acoustic noise in a magnetic resonance imaging (MRI) device including one or more inflatable support elements that position the gradient coil assembly within the magnet bore and provide vibration isolation between the gradient coil assembly and external structures of the MRI device.

The inflatable support element or elements may be underneath the gradient winding assembly, supporting its weight, or at other positions around the gradient winding assembly, defining the position of the gradient winding assembly. The pressure in the inflatable support element or elements may be adjustable in order to control the spring constants of the inflatable support element or elements in order to control the position of the gradient winding assembly, to control the motion of the gradient winding assembly and to control the vibration attenuation frequency transfer function between the gradient winding assembly and the external support structure.

In some embodiments, vibrations are created in the gradient winding assembly by the intense pulsed Lorentz forces on the wires embedded in the gradient winding assembly. Further, the wires carrying large pulsed currents to the gradient assembly may themselves be subject to intense pulsed Lorentz forces.

Vibrations directly created in the wires by Lorentz forces, or vibrations in the gradient winding assembly, can be conveyed mechanically from the gradient winding assembly via the wires, hoses, video inspection fiber optic cables or any other connections that must penetrate through any enclosure containing the gradient winding assembly and cause vibrations in the gradient winding enclosure, the cryostat, or other external parts of the MRI device. These vibrations can then produce acoustic noise, which may be heard by the MRI imaging subject and MRI operators and physicians.

Such wires, water hoses, and inspection fiber optics may also be set vibrating by connections outside of the gradient winding assembly enclosure, for example, by electrical connections within the strong static MRI magnetic field that are subject to pulsed Lorentz forces resulting from the application of pulsed currents through wires. These vibrations can also be transferred to solid parts of the MRI scanner and cause acoustic noise.

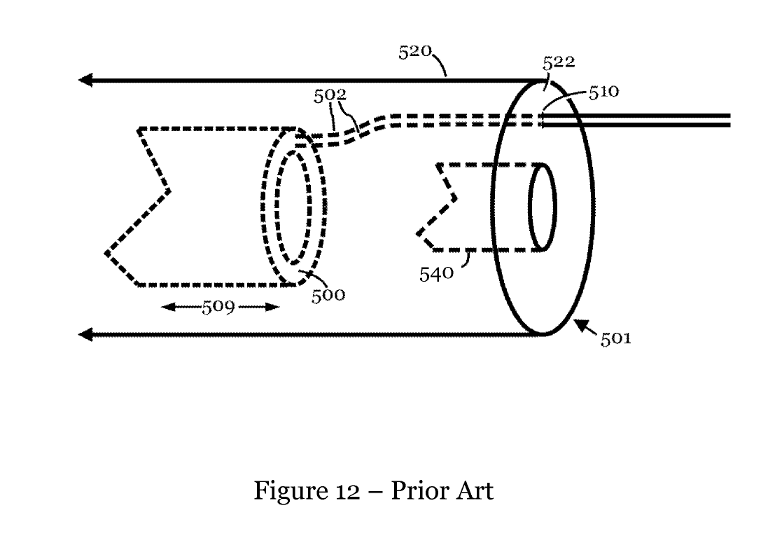

FIG. 12 is a schematic illustration of a typical gradient winding assembly 500 contained in an enclosure 501. As shown, wires, water hoses, inspection fiber optic links, or other solid connecting links are represented schematically by connecting elements 502. These connecting elements 502 may pass through the containing enclosure.

Continuing to refer to FIG. 12, the gradient winding assembly enclosure 501 can be comprised of outer cylinder 520 and inner cylinder 540 sealed against end flange, or end cap, 522. The opposite ends of cylinders 540 and 520 are also sealed against a similar end cap 522 (not shown). The volume between the outer diameter of cylinder 540 and the inner diameter of cylinder 520 thus forms an airtight annular region 509 in which is situated gradient winding assembly 500.

In the structure of FIG. 12, vibrations of the gradient winding assembly 500 can be quite large in clinical or animal scanners. These vibrations may be mechanically conveyed via connecting elements 502. Connecting elements 502 go from gradient winding assembly 500 and penetrate to the outside world through an end flange, or end cap, 522, in which connecting elements 502 may be securely glued into end cap 522.

In some embodiments, it is desirable to reduce or stop vibration on wires or other connections that create vibrations in the gradient enclosure 501 or in structures outside of gradient enclosure 501.

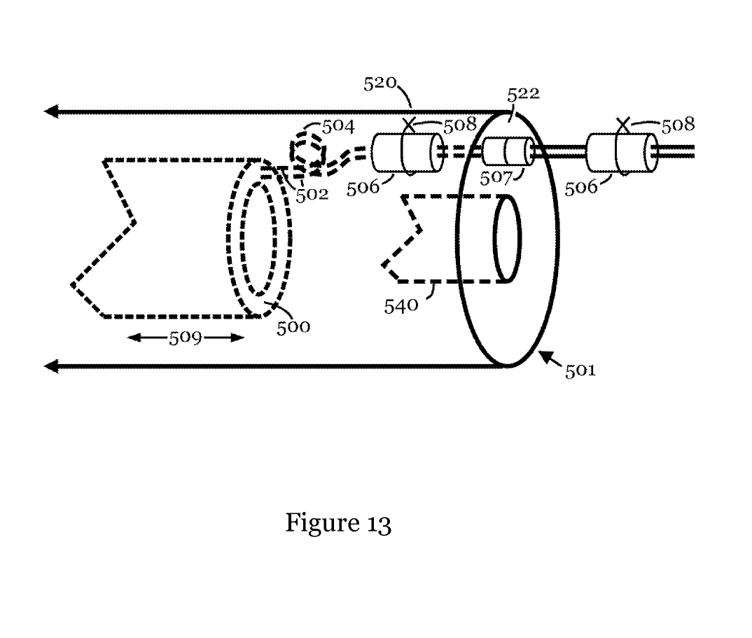

According to one embodiment, FIG. 13 illustrates a cross-sectional side view of a gradient assembly 500 contained in an enclosure 501 and connecting elements 502. In this embodiment, connecting elements 502 may include one or more strain relief loop elements 504 that decrease the stiffness of the connecting elements 502 between gradient winding assembly 500 and end cap 522. Reducing the stiffness via strain relief loops may decrease the efficiency of energy transfer created by vibrations from gradient winding assembly 500 and end cap 522. This may reduce the acoustic noise created by such vibrations.

Also illustrated in FIG. 13 is a further embodiment which may include wrapping the connecting elements 502 with a vibration reducing element 506. Vibration reducing element 506 can include a material that reduces vibrations, for example, rubber or other damping/elastic wrapping materials wrapped tightly onto the connecting elements 502 and secured onto connecting elements 502 by at least one securing element 508. Securing element 508 could, for example, be string, plastic tie wraps, rubber bands, or rubber tubing. It is to be understood that the wrapped vibration reducing element 506 may be secured by one or a plurality of securing elements of the same or different types, which will simply be referred to herein as securing element 508. The vibration reducing element 506 may help prevent transmission of vibrations along connecting elements 502 by absorption of vibration energy and also by virtue of the inertial mass of vibration reducing element 506.

In some embodiments, as illustrated in FIG. 13, one vibration reducing element 506, comprising for instance a vibration reducing material tightly wrapped around connecting element 502, is positioned between the gradient winding assembly 500 and enclosure end cap 522 to prevent transmissions of vibrations between gradient winding assembly 500 and the enclosure end cap 522. As illustrated, a second vibration reducing element 506 is positioned outside the gradient winding assembly enclosure 501 to prevent transmission of vibrations created beyond the gradient winding assembly enclosure 501 to the gradient winding assembly enclosure 501, and to reduce vibrations traveling from the enclosure 501 outward. It should be understood that the use of two separate instances of vibration reducing elements 506 is only illustrative, and any number of vibration reducing element 506 may be used. Further, multiple vibration reducing elements 506 may consist of the same or different materials.

FIG. 13 also shows a further embodiment comprising a vibration reducing element 507, which may consist of rubber, an elastomer, or other elastic/damping materials, and which may be wrapped tightly onto connecting elements 502. In this embodiment, vibration reducing element 507 may be wrapped around connecting elements and pushed into a hole in end cap 522, which may be a single piece of material extending both inside and outside gradient winding assembly enclosure 501. Vibration reducing element 507 may be sealed to end cap 522 with a sealant, such as silicone rubber sealant or other sealing materials, to keep annular region 509 airtight. In a further embodiment, vibration reducing element 507 may comprise one or more vibration reducing materials that are inserted into a hole in end cap 522, rather than wrapped, through which connecting elements 502 are pushed. In such an embodiment, vibration reducing element 507 may still be a single, solid piece of material inserted into the hole, and connecting elements 502 can be run through the material. Although examples of vibration reducing elements 506 and 507 are given above, it should be noted that any now known or later developed material that reduces vibrations and the transfer of vibrations may be used in embodiments of the invention.

It should be understood that any vibration reducing element 506 may be wrapped around one or multiple connection elements 502. It should also be understood that any single connection elements 502 or bundle of multiple connection elements 502 may be wrapped by one or more vibration reducing element 506. Further, each vibration reducing element 506 and 507 may be secured by one or more securing elements 508.

It should also be understood that vibration reducing element 507 can contain within it one or multiple connecting elements 502, as well.

In some embodiments, large pulsed electrical currents, typically 200 A or more, with risetimes and durations typically in the submillisecond to millisecond range, may be applied to the windings, as previously discussed. Because these windings are located in strong static magnetic fields, the currents interact with the static field and strong Lorentz forces are exerted on different parts of the gradient coil assembly. These forces in turn move, compress, expand, bend or otherwise distort the gradient coil assembly.

The moving gradient assembly surfaces may then act as loudspeakers and generate sound pressure waves that can be conveyed through the air around any tube or structure containing the patient. These sound pressure waves may very well reach the patient. They may also reach any staff or physicians in the vicinity of the imaging system.

Even if the sound pressure waves encounter a solid barrier, they may still set up a vibration of the barrier, which can in turn generate sound pressure waves emanating from the other side of the barrier. This is one way sound may travel “through” solid barriers.

In previous embodiments, one way of stopping the airborne sound pressure waves generated by the gradient assembly surfaces was to enclose the gradient assembly in a closed container and remove the air via a vacuum pump. Sound theoretically cannot travel through a vacuum, and the energy of transmitted sound is proportional to P², where P is the air or gas pressure. Thus a decrease in pressure by a factor of 100 from one atmosphere (1 bar, 760 mm Hg) to 0.01 atmosphere (7.6 mm Hg) will decrease the transmitted sound energy by a factor of about 10,000 or 40 decibels (dB).

However, creating a vacuum is not an easy or a cheap process. It involves vacuum pumps and careful attention to any possible leaks. Also, if it is desirable to achieve a very low pressure, then care must be taken to use only low vapor pressure materials and materials that cannot trap gases or vapors in the vacuum chamber.

Further complicating this process is the fact that as pressure decreases, the threshold for arcing also decreases until a pressure of approximately 1 mm Hg is achieved (the Paschen minimum for air) after which the arcing threshold begins to increase again. This arcing is a problem for any radiofrequency transmit coil that is contained in the vacuum space. Achieving a vacuum well below 1 mm Hg requires sophisticated pumps and increasingly careful (and expensive) attention to leaks and outgassing.

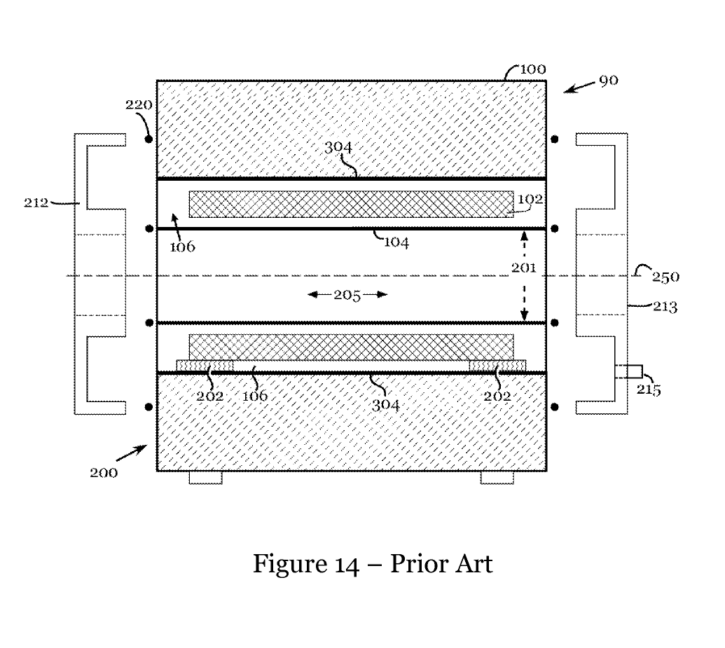

FIG. 14 is a schematic illustration of an MRI device 90 which shows, according to prior art embodiments, a vacuum port 215, attached to end cap seal 213, that can be attached to a vacuum pump to evacuate the air in region 106 around gradient winding assembly 102. The vacuum decreases, to some degree, the transmission of sound created by vibration of the gradient winding assembly 102, to the boundaries of region 106 (such as patient bore 104 and end cap covers 212) and subsequently out of region 106 to the patient imaging volume 205 or elsewhere beyond the magnet system.

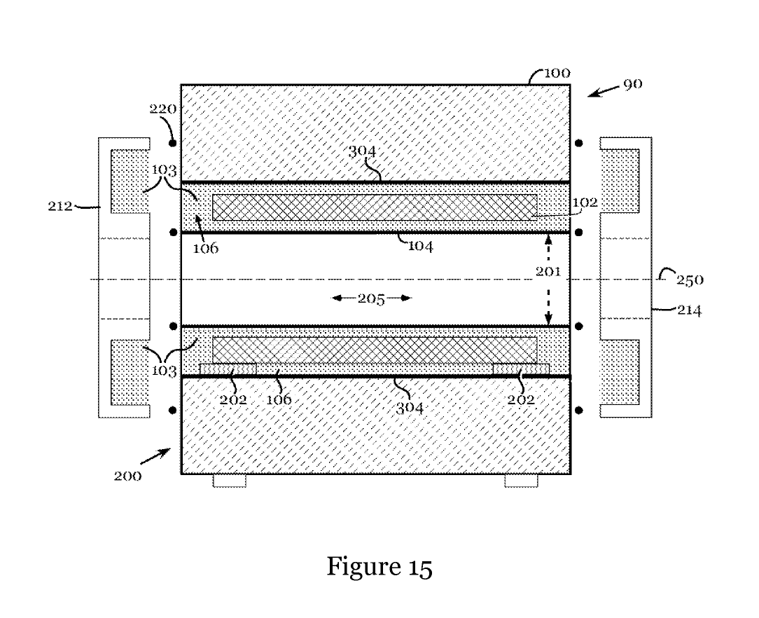

FIG. 15 shows, according to an embodiment of the present invention, MRI device 90 with region 106 closed by end cap covers 213 and 214. When end cap covers 212 and 214 are secured against rubber gaskets 220 positioned between end cap covers 212 and 214 and cryostat shell 100, and secured against other rubber gaskets 220 positioned between end cap covers 212 and 214 and patient tube 104, region 106 becomes an airtight space containing the gradient winding assembly 102.

As illustrated in FIG. 15, end cap covers 212 and 214 may not have a vacuum port. Rather, an acoustic noise absorbing material 103 may be placed within the airtight region 106 to prevent the airborne transmission of sound, created by vibration of the gradient winding assembly 102. The acoustic noise absorbing material 103 may partially fill or completely fill airtight region 106. Acoustic noise absorbing material may take numerous forms and combinations of forms. It could comprise a single sound absorbing material, such as foam. In another embodiment, acoustic noise absorbing material 103 could comprise sound barrier structures consisting of alternating layers of sound absorbing materials and sound reflecting materials. The sound absorbing materials may include foam or insulation, as non-limiting examples. The sound reflecting material may include relatively harder plastic or some form of metal, as well as any other now known or later developed sound reflecting material. Acoustic noise absorbing material 103 may also include air spaces, or voids within the material. Any combination of these materials, layers, and/or voids may be utilized in acoustic noise absorbing material 103. It should also be understood that at least partially filling airtight region 106 may include attaching noise absorbing material 103 to at least one of the surfaces of patient bore 104 or warm bore 304 within airtight region 106.

Although region 106 in FIG. 15 may not be evacuated, it should be sealed to form an airtight space so that sounds originating within region 106 cannot escape. In further embodiments, region 106 may be fully or partially evacuated, creating a pressure of less than 1 atmosphere.

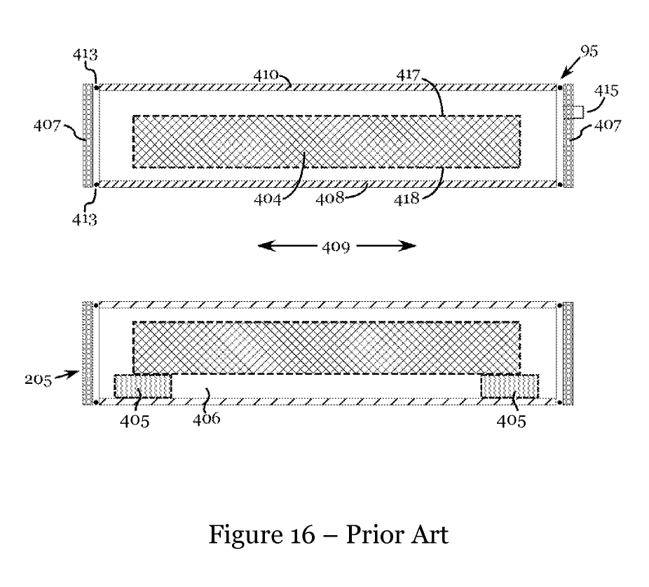

FIG. 16 illustrates an insertable gradient fixture 95, typically for use with small animal imaging systems, according to prior art. Gradient winding assembly 404 is enclosed in an annular container 205. Gradient winding assembly 404 is supported by mounts 405. Gradient winding assembly 404 may be attached at its ends to annular flanges 407 which can be secured by O-rings 420 to the inside of the outer wall 410 of the annular container 205, and also by O-rings to the inner wall 408 of the annular container 205. It is also possible to use adhesives or other materials to secure end flanges 407 to the annular container inner wall 408 and outer wall 410. Annular container 205 may be airtight.

FIG. 16 shows vacuum port 415, through annular flange 407, that can be attached to a vacuum pump to evacuate the air in region 406. The vacuum can decrease, to some extent, the transmission of sound, created by vibration of the gradient winding assembly 102, to the boundaries of region 406—such as annular container inner wall 408, outer wall 410, and end cap covers 407—and subsequently out of region 406 to the imaging volume 409 or elsewhere beyond the magnet system.

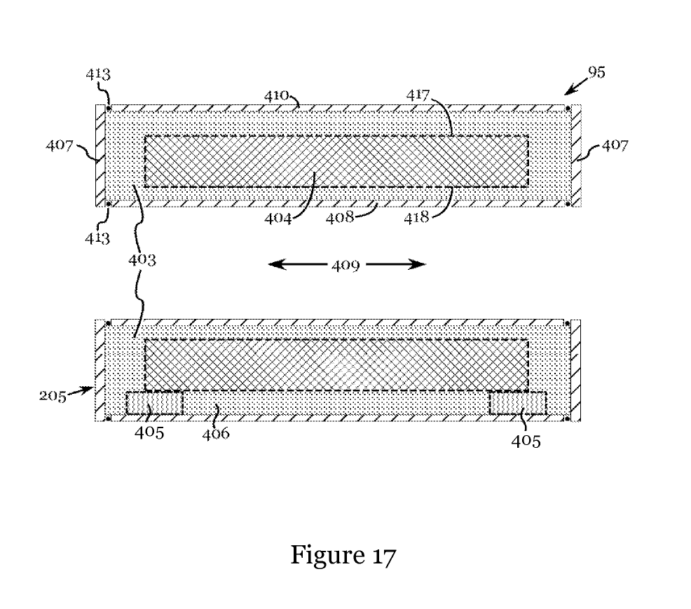

FIG. 17 shows insertable gradient fixture 95 according to some embodiments of the present invention. For instance, acoustic noise absorbing material 403 is inserted, and no vacuum port exists, similar to the description of FIG. 15 depicting an entire MRI device, rather than just insertable gradient fixture 95. In the embodiment illustrated in FIG. 17, the acoustic noise absorbing material 403 replaces the intended function of a vacuum and decreases the transmission of sound created by vibrations of the gradient assembly 404.

As described in reference to FIG. 15 above, acoustic noise absorbing material 403, like 103 in FIG. 15, can take numerous forms and combinations of forms in this insertable form as well. It could be a single sound absorbing material, or it could be sound barrier structures consisting of alternating layers of sound absorbing materials and sound reflecting materials. It can also include air spaces or voids within the acoustic noise absorbing material 403.

It is also possible to evacuate or partially evacuate the airtight regions 106 in the clinical system (FIG. 15) or region 406 in the insertable gradient winding structure (FIG. 17) so that the reduced pressure works in combination with acoustic noise absorbing material 103 or 403.

According to some embodiment of the current invention, the enclosed systems may reduce acoustic noise due to vibration transmission, as well as blocking or absorbing the vibrations, reducing sound transmission. Further, any combination of the disclosed embodiments may be utilized together.

The foregoing description of various aspects of the invention has been presented for the purpose of illustration and description. It is not intended to be exhaustive or to limit the invention to the precise form disclosed, and obviously, many modifications and variations are possible. Such variations and modifications that may be apparent to one skilled in the art are intended to be included within the scope of the present invention as defined by the accompanying claims.

What is claimed is:

1. A magnetic resonance imaging (MRI) device noise dampening system, comprising:
an adjustable vibration dampening suspension system arranged between a gradient winding assembly of the MRI device and a support structure supported by a primary magnet assembly of an MRI device, wherein the adjustable vibration dampening suspension system comprises a plurality of separately inflatable support elements.

2. The magnetic resonance imaging (MRI) device noise dampening system of claim 1, wherein the separately inflatable support elements are arranged to further provide at least partial alignment of the gradient winding assembly with respect to the primary magnet assembly.

3. The magnetic resonance imaging (MRI) device noise dampening system of claim 1, wherein the suspension system further comprises a pressure control system to selectively control a pressure with respect to each of the plurality of separately inflatable support elements.

4. The magnetic resonance imaging (MRI) device noise dampening system of claim 3, wherein the suspension system further comprises a pressure monitoring system to measure the pressure of each of the plurality of separately inflatable support elements.

5. The magnetic resonance imaging (MRI) device noise dampening system of claim 1, wherein a first separately inflatable support element of the plurality of separately inflatable support elements is arranged at one of a group comprising: a top vertical position of the MRI device and a bottom vertical position of the MRI device.

6. The magnetic resonance imaging (MRI) device noise dampening system of claim 5, wherein the suspension system further comprises a second separately inflatable support element and a third separately inflatable support element arranged approximately 120 degrees apart with respect to the first separately inflatable support element.

7. The magnetic resonance imaging (MRI) device noise dampening system of claim 5, wherein a second separately inflatable support element of the plurality of separately inflatable support elements is arranged at the other of the group comprising: a top vertical position of the MRI device and a bottom vertical position of the MRI device.

8. The magnetic resonance imaging (MRI) device noise dampening system of claim 7, wherein the suspension system further comprises a third separately inflatable support element and a fourth separately inflatable support element arranged at substantially horizontal, opposing side positions in the MRI device.

9. The magnetic resonance imaging (MRI) device noise dampening system of claim 1, further comprising:
a vibration reducing material coupled to at least one of a plurality of connecting elements associated with the gradient winding assembly.

10. The magnetic resonance imaging (MRI) device noise dampening system of claim 1, further comprising:
an acoustic noise absorbing material at least partially filling a space containing a gradient winding assembly of an MRI device.

11. A magnetic resonance imaging (MRI) device noise dampening system, comprising:
a vibration reducing material coupled to at least one of a plurality of connecting elements associated with a gradient winding assembly of an MRI device.

12. The magnetic resonance imaging (MRI) device noise dampening system of claim 11, wherein the vibration reducing material comprises an elastomer.

13. The magnetic resonance imaging (MRI) device noise dampening system of claim 11, wherein the vibration reducing material is inserted into at least one end cap associated with the gradient winding assembly, wherein the vibration reducing material comprises a single piece and extends inside and outside the gradient winding assembly.

14. The magnetic resonance imaging (MRI) device noise dampening system of claim 11, wherein the vibration reducing material comprises a wrapping material which is wrapped and secured with at least one securing element to at least one of a plurality of connecting elements associated with the gradient winding assembly.

15. The magnetic resonance imaging (MRI) device noise dampening system of claim 14, wherein the wrapping material is wrapped and secured to the plurality of connecting elements.

16. The magnetic resonance imaging (MRI) device noise dampening system of claim 11, further comprising:
an adjustable vibration dampening suspension system arranged between the gradient winding assembly of the MRI device and a support structure supported by a primary magnet assembly of an MRI device, wherein the adjustable vibration dampening suspension system comprises a plurality of separately inflatable support elements.

17. The magnetic resonance imaging (MRI) device noise dampening system of claim 11, further comprising:
an acoustic noise absorbing material at least partially filling a space containing a gradient winding assembly of an MRI device.

18. A magnetic resonance imaging (MRI) device noise dampening system, comprising:
an acoustic noise absorbing material at least partially filling a space containing a gradient winding assembly of an MRI device.

19. The magnetic resonance imaging (MRI) device noise dampening system of claim 18, further comprising:
a plurality of voids comprising air at least partially filling a space containing the gradient winding assembly of the MRI device.

20. The magnetic resonance imaging (MRI) device noise dampening system of claim 18, wherein the acoustic noise absorbing material comprises a type of foam.

21. The magnetic resonance imaging (MRI) device noise dampening system of claim 18, wherein the acoustic noise absorbing material comprises a plurality of layers.

22. The magnetic resonance imaging (MRI) device noise dampening system of claim 21, wherein the plurality of layers consist of alternating layers of a sound absorbing material and a sound reflecting material.

23. The magnetic resonance imaging (MRI) device noise dampening system of claim 18, wherein the space containing the gradient winding assembly of the MRI device has a pressure less than atmosphere.

24. The magnetic resonance imaging (MRI) device noise dampening system of claim 18, further comprising:
an adjustable vibration dampening suspension system arranged between a gradient winding assembly of the MRI device and a support structure supported by a primary magnet assembly of an MRI device, wherein the adjustable vibration dampening suspension system comprises a plurality of separately inflatable support elements.

25. The magnetic resonance imaging (MRI) device noise dampening system of claim 18, further comprising:
a vibration reducing material coupled to at least one of a plurality of connecting elements associated with the gradient winding assembly.

26. A magnetic resonance imaging (MRI) device noise dampening system, comprising:
an adjustable vibration dampening suspension system arranged between a gradient winding assembly of the MRI device and a support structure supported by a primary magnet assembly of an MRI device, wherein the adjustable vibration dampening suspension system comprises a plurality of separately inflatable support elements;
a vibration reducing material coupled to at least one of a plurality of connecting elements associated with the gradient winding assembly; and
an acoustic noise absorbing material at least partially filling a space containing a gradient winding assembly of an MRI device.
